(19) United States
(12) Patent Application Publication
(10) Pub. No.: US 2012/0028395 A1
(43) Pub. Date: Feb. 2, 2012

(54) VAPOR DEPOSITION PROCESS FOR CONTINUOUS DEPOSITION AND TREATMENT OF A THIN FILM LAYER ON A SUBSTRATE

(75) Inventor: Scott Daniel Feldman-Peabody, Golden, CO (US)

(73) Assignee: PRIMESTAR SOLAR, INC., Arvada, CO (US)

(21) Appl. No.: 12/977,161

(22) Filed: Dec. 23, 2010

(51) Int. Cl. H01L 31/18

(52) U.S. Cl. 438/61; 257/E31.015

(57) ABSTRACT

An integrated apparatus is provided for vapor deposition of a sublimated source material as a thin film on a photovoltaic module substrate and subsequent vapor treatment. The apparatus can include a load vacuum chamber, a first vapor deposition chamber; and a second vapor deposition chamber that are integrally connected such that substrates being transported through the apparatus are kept at a system pressure less than about 760 Torr. A conveyor system can be operably disposed within the apparatus and configured for transporting substrates in a serial arrangement into and through load vacuum chamber, into and through the first vapor deposition chamber, and into and through the second vapor deposition chamber at a controlled speed. Processes are also provided for manufacturing a thin film cadmium telluride thin film photovoltaic device.

### FIELD OF THE INVENTION

The subject matter disclosed herein relates generally to methods and systems for depositing thin films during manufacture of cadmium telluride photovoltaic devices. More particularly, the subject matter disclosed herein relates generally to integrated systems for the deposition of a cadmium telluride layer and subsequent cadmium chloride treatment during manufacture of cadmium telluride photovoltaic devices, and their methods of use.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials.

The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., a positive, electron accepting layer) and the CdS layer acts as a n-type layer (i.e., a negative, electron donating layer). Free carrier pairs are created by light energy and then separated by the p-n heterojunction to produce an electrical current.

During the production of CdTe PV modules, the surface of the CdTe PV module is typically cooled, transported to a subsequent treatment apparatus for cadmium chloride treatment (e.g., a cadmium chloride wash), and then subsequently annealed. This process of heating, cooling, and re-heating is inefficient in both energy consumption and cost. Additionally, the cadmium telluride layer is exposed to the environment during transport to the subsequent treatment apparatus. Such exposure can result in the introduction of additional atmospheric materials into the cadmium telluride layer, which can lead to the introduction of impurities in the CdTe PV module. Additionally, the room atmosphere naturally varies over time, adding a variable to a large-scale manufacturing process of the CdTe PV modules. Such impurities and additional variables can lead to inconsistent CdTe PV modules from the same manufacturing line and process.

Thus, a need exists for methods and systems for reducing the introduction of impurities and additional variables into a large-scale manufacturing process of making the CdTe PV modules, as well as increasing the energy efficiency of the process.

### BRIEF DESCRIPTION OF THE INVENTION

Aspects and advantages of the invention will be set forth in part in the following description, or may be obvious from the description, or may be learned through practice of the invention.

An integrated apparatus is generally provided for sequential vapor deposition of a sublimated source material as a thin film on a photovoltaic (PV) module substrate and vapor treatment of the thin film. The apparatus can include a load vacuum chamber, a first vapor deposition chamber; and a second vapor deposition chamber that are integrally connected such that substrates being transported through the apparatus are kept at a system pressure less than about 760 Torr. The load vacuum chamber can be connected to a load vacuum pump configured to reduce the pressure within the load vacuum chamber to an initial load pressure. A conveyor system can be operably disposed within the apparatus and configured for transporting substrates in a serial arrangement into and through load vacuum chamber, into and through the first vapor deposition chamber, and into and through the second vapor deposition chamber at a controlled speed.

Processes are also provided for manufacturing a thin film cadmium telluride thin film photovoltaic device. The substrate can be first transferred into a load vacuum chamber connected to a load vacuum pump, and a vacuum drawn in the load vacuum chamber using the load vacuum pump until an initial load pressure is reached in the load vacuum chamber. The substrate can then be transported from the load vacuum chamber into a first vapor deposition chamber. The first vapor deposition chamber comprises a source material (e.g., cadmium telluride), and a cadmium telluride layer can be deposited on the substrate by heating the source material to produce source vapors that deposit onto the substrate. The substrate can then be transported from the first vapor deposition chamber into a second vapor deposition chamber. The second vapor deposition chamber comprises a treatment material (e.g., cadmium chloride), and the cadmium telluride layer can be treated by heating the treatment material to produce treatment vapors that deposit onto the substrate. In the process, the substrate is transported through the first vapor deposition chamber and the second vapor deposition chamber at a system pressure that is less than about 760 Torr.

These and other features, aspects, and advantages of the present invention will become better understood with reference to the following description and appended claims, or may be obvious from the description or claims, or may be learned through practice of the invention.

### BRIEF DESCRIPTION OF THE DRAWINGS

A full and enabling disclosure of the present invention, including the best mode thereof, is set forth in the specification, which makes reference to the appended drawings, in which:

FIG. 1 is a plan view of a system that may incorporate embodiments of a vapor deposition apparatus of the present invention;

FIG. 2 is a cross-sectional view of an embodiment of a vapor deposition apparatus according to aspects of the invention in a first operational configuration;

FIG. 3 is a cross-sectional view of the embodiment of FIG. 2 in a second operational configuration;

FIG. 4 is a cross-sectional view of the embodiment of FIG. 2 in cooperation with a substrate conveyor;

FIG. 5 is a top view of the receptacle component within the embodiment of FIG. 2; and,

FIG. 6 represents a diagram of an exemplary process according to one embodiment of the present invention.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment, can be used with another embodiment to yield a still further embodiment. Thus, it is intended that the present invention encompass such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers. Thus, these terms are simply describing the relative position of the layers to each other and do not necessarily mean “on top of” since the relative position above or below depends upon the orientation of the device to the viewer.

Additionally, although the invention is not limited to any particular film thickness, the term “thin” describing any film layers of the photovoltaic device generally refers to the film layer having a thickness less than about 10 micrometers (“microns” or “μm”).

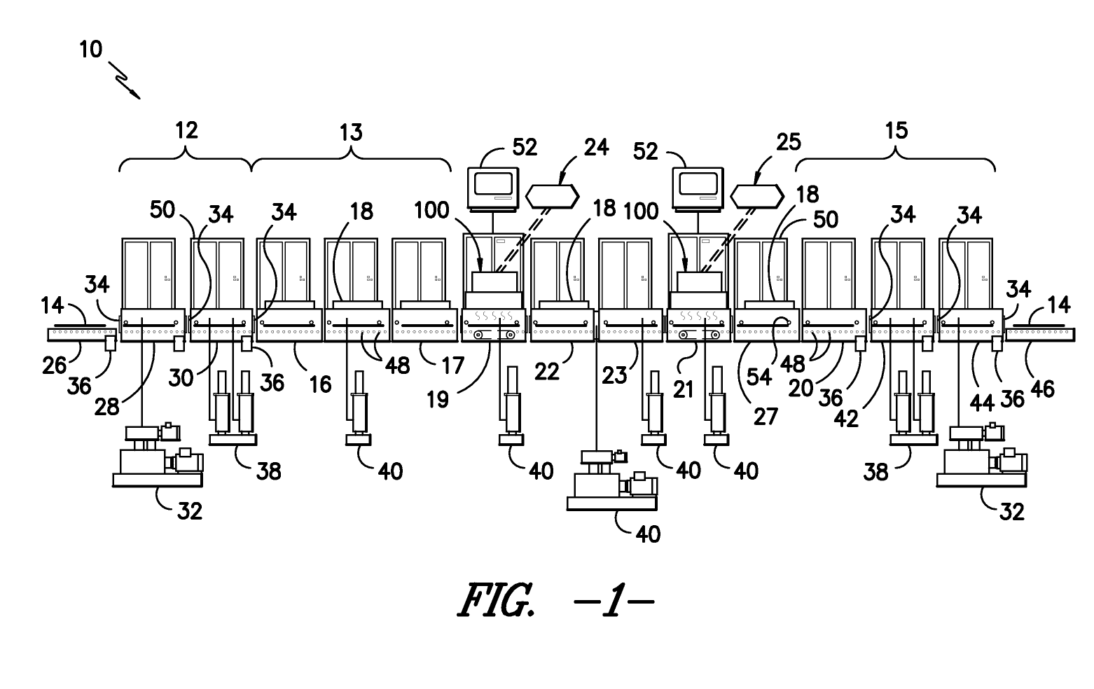

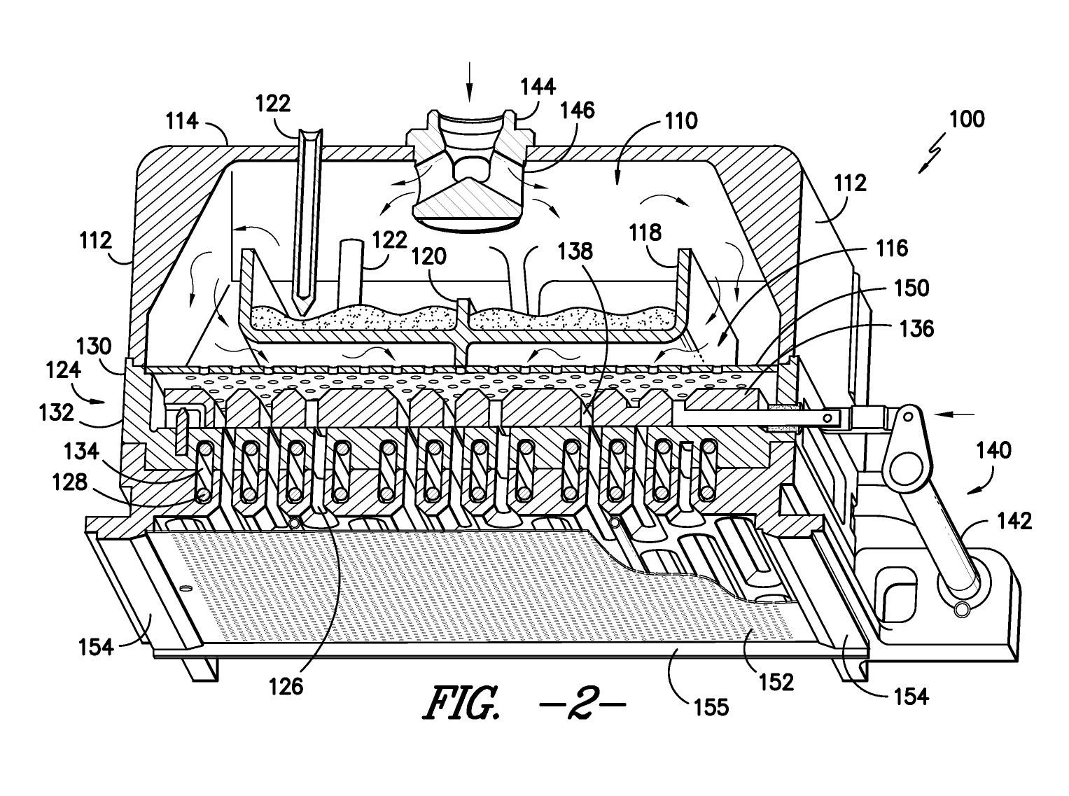

FIG. 1 illustrates an embodiment of a system 10 that may incorporate at least two vapor deposition apparatus 100 (FIGS. 2 through 5), sequentially positioned within the system in accordance with embodiments of the invention configured for deposition of a thin film layer on a photovoltaic (PV) module substrate 14 (referred to hereafter as a “substrate”) and subsequent treatment. The thin film may be, for example, a film layer of cadmium telluride (CdTe), and the subsequent treatment may be, for instance, cadmium chloride treatment to the cadmium telluride film layer. It should be appreciated that the present system 10 is not limited to the vapor deposition apparatus 100 illustrated in FIGS. 2-5. Other vapor deposition apparatus may be used in the system 10 for vapor deposition of a thin film layer onto a PV module substrate 14.

Referring to FIG. 1, the individual substrates 14 are initially placed onto a load conveyor 26, and are subsequently moved into an entry vacuum lock station 12 that includes a load vacuum chamber 28 and a load buffer chamber 30. A “rough” (i.e., initial) vacuum pump 32 is configured with the load vacuum chamber 28 to drawn an initial load pressure, and a “fine” (i.e., final) vacuum pump 38 is configured with the load buffer chamber 30 to increase the vacuum (i.e. decrease the initial load pressure) in the load buffer chamber 30 to reduce the vacuum pressure within the entry vacuum lock station 12. Valves 34 (e.g., gate-type slit valves or rotary-type flapper valves) are operably disposed between the load conveyor 26 and the load module 28, between the load vacuum chamber 28 and the load buffer chamber 30, and between the load vacuum chamber 30 and the heating station 13. These valves 34 are sequentially actuated by a motor or other type of actuating mechanism 36 in order to introduce the substrates 14 into the vacuum station 12 in a step-wise manner without affecting the vacuum within the subsequent heating station 13.

In operation of the system 10, an operational vacuum is maintained in the system 10 by way of any combination of rough and/or fine vacuum pumps 40. In order to introduce a substrate 14 into the load vacuum station 12, the load vacuum chamber 28 and load buffer chamber 30 are initially vented (with the valve 34 between the two modules in the open position). The valve 34 between the load buffer chamber 30 and the first heater module 16 is closed. The valve 34 between the load vacuum chamber 28 and load conveyor 26 is opened and a substrate 14 is moved into the load vacuum chamber 28. At this point, the first valve 34 is shut and the rough vacuum pump 32 then draws an initial vacuum in the load vacuum chamber 28 and load buffer chamber 30. The substrate 14 is then conveyed into the load buffer chamber 30, and the valve 34 between the load vacuum chamber 28 and load buffer chamber 30 is closed. The fine vacuum pump 38 then increases the vacuum in the load buffer chamber 30 to approximately the same vacuum in the heating station 13. At this point, the valve 34 between the load buffer chamber 30 and heating station 13 is opened and the substrate 14 is conveyed into the first heater module 16.

Thus, the substrates 14 are transported into the exemplary system 10 first through the load vacuum chamber 28 that draws a vacuum in the load vacuum chamber 12 to an initial load pressure. For example, the initial load pressure can be less than about 250 mTorr, such as about 1 mTorr to about 100 mTorr. Optionally, a load buffer chamber can reduce the pressure to about 1×10⁻⁷ Torr to about 1×10⁻⁴ Torr, and then backfilled with an inert gas (e.g., argon) in a subsequent chamber within the system 10 (e.g., within the sputtering deposition chamber 112) to a deposition pressure (e.g., about 10 mTorr to about 100 mTorr).

The substrates 14 can then be transported into and through a heating station 13 including heating chambers 16. The plurality of heating chambers 16 define a pre-heat section 13 of the system 10 through which the substrates 14 are conveyed and heated to a first deposition temperature before being conveyed into the vapor deposition chamber 19. Each of the heating chambers 16 may include a plurality of independently controlled heaters 18, with the heaters defining a plurality of different heat zones. A particular heat zone may include more than one heater 18. The heating chambers 16 can heat the substrates 14 to a deposition temperature, such as about 350° C. to about 600° C. Although shown with three heating chambers 16, any suitable number of heating chambers 16 can be utilized.

The substrates 14 can then be transferred into and through the first vapor deposition chamber 19 for deposition of a thin film onto the substrates 14, such as a cadmium telluride thin film. The first vapor deposition chamber 19 can include the deposition apparatus 100, such as shown in FIGS. 2-5 and discussed in greater detail below. As diagrammatically illustrated in FIG. 1, a first feed device 24 is configured with the vapor deposition apparatus 100 to supply source material, such as granular cadmium telluride. The feed device 24 may take on various configurations within the scope and spirit of the invention, and functions to supply the source material without interrupting the continuous vapor deposition process within the apparatus 100 or conveyance of the substrates 14 through the apparatus 100.

After deposition of the thin film in the first vapor deposition chamber 19, the substrates 14 can be transported into and through a second vapor deposition chamber 21 for subsequent vapor treatment of the thin film. The second vapor deposition chamber 21 can also include the deposition apparatus 100, such as shown in FIGS. 2-5. As diagrammatically illustrated in FIG. 1, a second feed device 25 is configured with the vapor deposition apparatus 100 to supply treatment material, such as cadmium chloride. The second feed device 24 may take on various configurations within the scope and spirit of the invention, and functions to supply the source material without interrupting the continuous vapor deposition process within the apparatus 100 or conveyance of the substrates 14 through the apparatus 100. Thus, the cadmium telluride thin film on the substrates 14 can be treated with cadmium chloride within the system 10 without prior exposure to the outside environment.

Between the first vapor deposition chamber 19 and the second vapor deposition chamber 21 a heating chamber, the substrates 14 can be transported into and through a post-heat chamber 22 and first cooling chamber 23. In the illustrated embodiment of system 10, at least one post-heat chamber 22 is located immediately downstream of the vapor deposition apparatus 100 and upstream of the second vapor deposition chamber 21 in a conveyance direction of the substrates 14. The post-heat chamber 22 maintains a controlled heating profile of the substrate 14 until the entire substrate is moved out of the first vapor deposition chamber 19 to prevent damage to the substrate 14, such as warping or breaking caused by uncontrolled or drastic thermal stresses. If the leading section of the substrate 14 were allowed to cool at an excessive rate as it exited the apparatus 100, a potentially damaging temperature gradient would be generated longitudinally along the substrate 14. This condition could result in breaking, cracking, or warping of the substrate from thermal stress.

Then, the substrates 14 can be cooled in the first cooling chamber 23 to a vapor treatment temperature prior to entering the second vapor deposition chamber 21. For example, first cooling chamber 23 can subsequently cool the substrates to a vapor treatment temperature that is less than the deposition temperature prior to entering the second vapor deposition chamber 21. The treatment temperature can be, for instance, about 20° C. to about the anneal temperature discussed below.

The substrates 14 can be transported from the second vapor deposition chamber 21 into the anneal chamber 27 heated by heater 18. The substrates 14 can be annealed in the anneal chamber 27 by heating to an anneal temperature of 350° C. to about 500° C. after treatment of the cadmium telluride layer with the cadmium chloride vapors, such as about 375° C. to about 450° C. or about 390° C. to about 420° C.

A cool-down chamber 20 is positioned downstream of the first vapor deposition chamber 19 and the second deposition chamber 21. The cool-down chamber 20 allow the substrates 14 having the treated thin film are conveyed and cooled at a controlled cool-down rate prior to the substrates 14 being removed from the system 10. The cool down chamber 20 may include a forced cooling system wherein a cooling medium, such as chilled water, refrigerant, gas, or other medium, is pumped through cooling coils (not illustrated) configured with the chamber 20. In other embodiments, a plurality of cool down chambers 20 can be utilized in the system 10.

An exit vacuum lock station 15 is configured downstream of the cool-down chamber 20, and operates essentially in reverse of the entry vacuum lock station 12 described above. For example, the exit vacuum lock station 15 may include an exit buffer module 42 and a downstream exit lock module 44. Sequentially operated valves 34 are disposed between the buffer module 42 and the last one of the cool-down modules 20, between the buffer module 42 and the exit lock module 44, and between the exit lock module 44 and an exit conveyor 46. A fine vacuum pump 38 is configured with the exit buffer module 42, and a rough vacuum pump 32 is configured with the exit lock module 44. The pumps 32, 38 and valves 34 are sequentially operated to move the substrates 14 out of the system 10 in a step-wise fashion without loss of vacuum condition within the system 10.

System 10 also includes a conveyor system configured to move the substrates 14 into, through, and out of each of load vacuum station 12, the pre-heating station 12, the first vapor deposition chamber 19, the post-heat chamber 22, the first cooling chamber 23, the second vapor deposition chamber 21, the annealing chamber 27, and the second cooling chamber 20. In the illustrated embodiment, this conveyor system includes a plurality of individually controlled conveyors 48, with each of the various modules including a respective one of the conveyors 48. It should be appreciated that the type or configuration of the conveyors 48 may vary. In the illustrated embodiment, the conveyors 48 are roller conveyors having rotatably driven rollers that are controlled so as to achieve a desired conveyance rate of the substrates 14 through the respective module and the system 10 overall.

As described, each of the various modules and respective conveyors in the system 10 are independently controlled to perform a particular function. For such control, each of the individual modules may have an associated independent controller 50 configured therewith to control the individual functions of the respective module. The plurality of controllers 50 may, in turn, be in communication with a central system controller 52, as diagrammatically illustrated in FIG. 1. The central system controller 52 can monitor and control (via the independent controllers 50) the functions of any one of the modules so as to achieve an overall desired heat-up rate, deposition rate, cool-down rate, conveyance rate, and so forth, in processing of the substrates 14 through the system 10.

Referring to FIG. 1, for independent control of the individual respective conveyors 48, each of the modules may include any manner of active or passive sensors 54 that detects the presence of the substrates 14 as they are conveyed through the module. The sensors 54 are in communication with the respective module controller 50, which is in turn in communication with the central controller 52. In this manner, the individual respective conveyor 48 may be controlled to ensure that a proper spacing between the substrates 14 is maintained and that the substrates 14 are conveyed at the desired conveyance rate through the vacuum chamber 12.

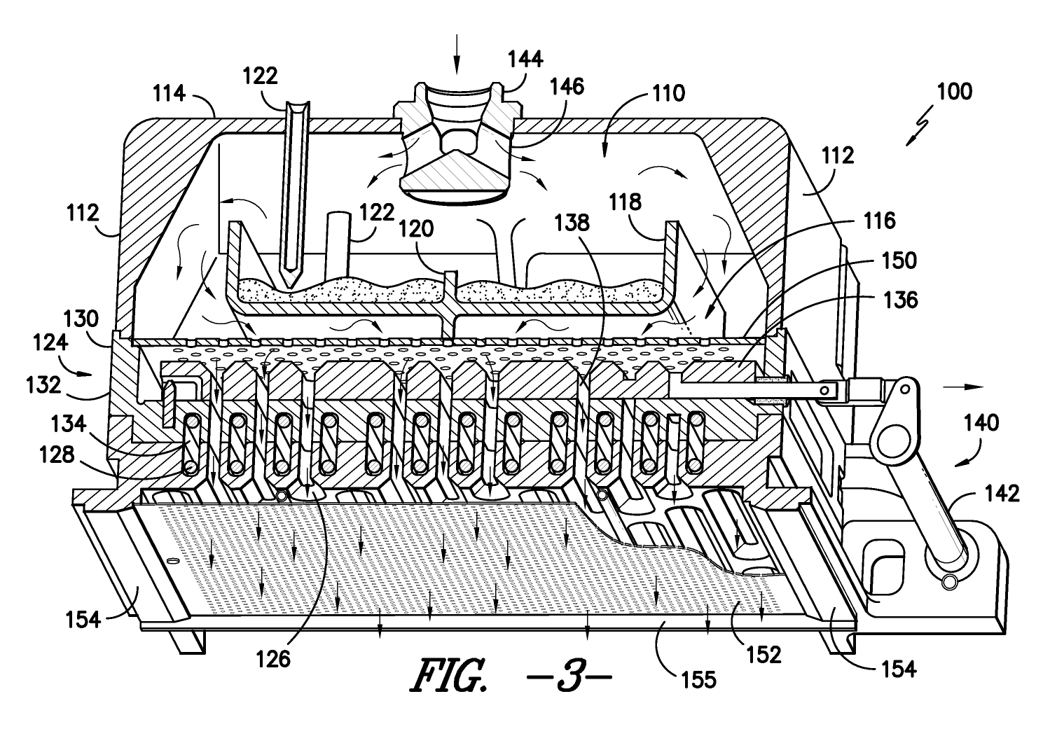

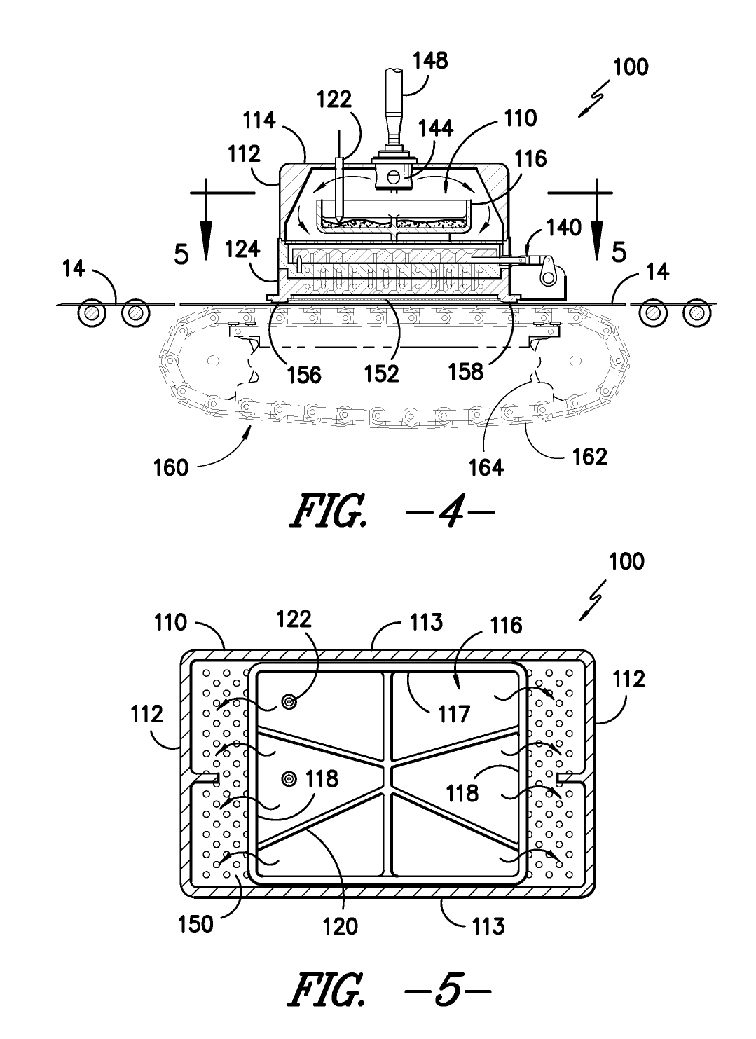

FIGS. 2 through 5 relate to a particular embodiment of the vapor deposition apparatus 100, that can be utilized in either or both of the first vapor deposition chamber 19 and/or the second vapor deposition chamber 21. Referring to FIGS. 2 and 3 in particular, the apparatus 100 includes a deposition head 110 defining an interior space in which a receptacle 116 is configured for receipt of a source material (not shown) or treatment material. As mentioned, the source material or treatment material may be supplied by a feed device or system 24, 25, respectively, via a feed tube 148 (FIG. 4). The feed tube 148 is connected to a distributor 144 disposed in an opening in a top wall 114 of the deposition head 110. The distributor 144 includes a plurality of discharge ports 146 that are configured to evenly distribute the granular source material into the receptacle 116. The receptacle 116 has an open top and may include any configuration of internal ribs 120 or other structural elements.

In the illustrated embodiment, at least one thermocouple 122 is operationally disposed through the top wall 114 of the deposition head 110 to monitor temperature within the deposition head 110 adjacent to or in the receptacle 116.

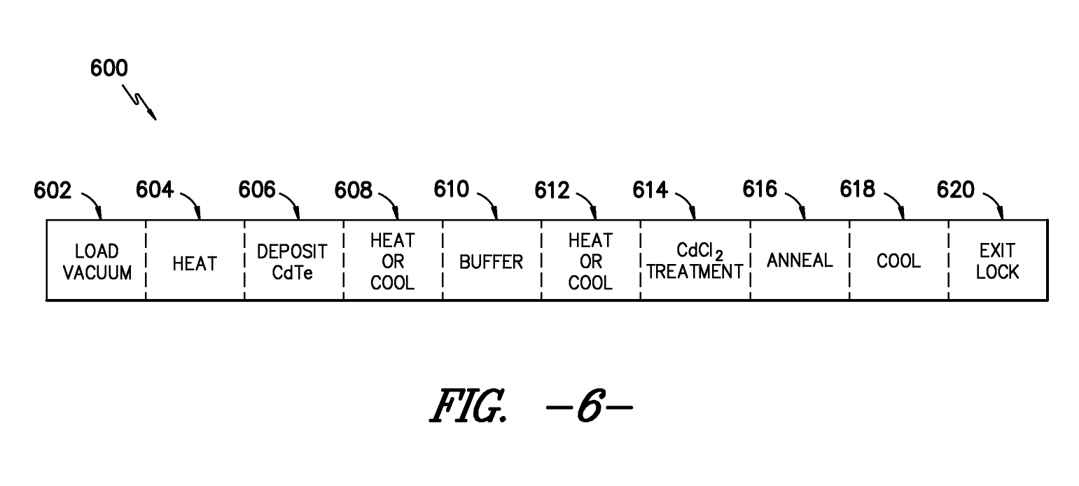

The deposition head 110 also includes longitudinal end walls 112 and side walls 113 (FIG. 5). Referring to FIG. 5 in particular, the receptacle 116 has a shape and configuration such that the transversely extending end walls 118 of the receptacle 116 are spaced from the end walls 112 of the head chamber 110. The longitudinally extending side walls 117 of the receptacle 116 lie adjacent to and in close proximation to the side walls 113 of the deposition head so that very little clearance exists between the respective walls, as depicted in FIG. 5. With this configuration, sublimated source material will flow out of the open top of the receptacle 116 and downwardly over the transverse end walls 118 as leading and trailing curtains of vapor 119 over, as depicted by the flow lines in FIGS. 2, 3, and 5. Very little of the sublimated source material will flow over the side walls 117 of the receptacle 116. The curtains of vapor 119 are “transversely” oriented in that they extend across the transverse dimension of the deposition head 110, which is generally perpendicular to the conveyance direction of the substrates through the system.

A heated distribution manifold 124 is disposed below the receptacle 116. This distribution manifold 124 may take on various configurations within the scope and spirit of the invention, and serves to indirectly heat the receptacle 116, as well as to distribute the sublimated source material that flows from the receptacle 116. In the illustrated embodiment, the heated distribution manifold 124 has a clam-shell configuration that includes an upper shell member 130 and a lower shell member 132. Each of the shell members 130, 132 includes recesses therein that define cavities 134 when the shell members are mated together as depicted in FIGS. 2 and 3. Heater elements 128 are disposed within the cavities 134 and serve to heat the distribution manifold 124 to a degree sufficient for indirectly heating the source material within the receptacle 116 to cause sublimation of the source material. The heater elements 128 may be made of a material that reacts with the source material vapor and, in this regard, the shell members 130, 132 also serve to isolate the heater elements 128 from contact with the source material vapor. The heat generated by the distribution manifold 124 is also sufficient to prevent the sublimated source material from plating out onto components of the head chamber 110. Desirably, the coolest component in the head chamber 110 is the upper surface of the substrates 14 conveyed therethrough so as to ensure that the sublimated source material plates onto the substrate, and not onto components of the head chamber 110.

Still referring to FIGS. 2 and 3, the heated distribution manifold 124 includes a plurality of passages 126 defined therethrough. These passages have a shape and configuration so as to uniformly distribute the sublimated source material towards the underlying substrates 14 (FIG. 4).

In the illustrated embodiment, a distribution plate 152 is disposed below the distribution manifold 124 at a defined distance above a horizontal plane of the upper surface of an underlying substrate 14, as depicted in FIG. 4. This distance may be, for example, between about 0.3 cm to about 4.0 cm. In a particular embodiment, the distance is about 1.0 cm. The conveyance rate of the substrates below the distribution plate 152 may be in the range of, for example, about 10 mm/sec to about 40 mm/sec. In a particular embodiment, this rate may be, for example, about 20 mm/sec. The thickness of the CdTe film layer that plates onto the upper surface of the substrate 14 can vary within the scope and spirit of the invention, and may be, for example, between about 1 micron to about 5 microns. In a particular embodiment, the film thickness may be about 3 microns.

The distribution plate 152 includes a pattern of passages, such as holes, slits, and the like, therethrough that further distribute the sublimated source material passing through the distribution manifold 124 such that the source material vapors are uninterrupted in the transverse direction. In other words, the pattern of passages are shaped and staggered or otherwise positioned to ensure that the sublimated source material is deposited completely over the substrate in the transverse direction so that longitudinal streaks or stripes of “un-coated” regions on the substrate are avoided.

As previously mentioned, a significant portion of the sublimated source material will flow out of the receptacle 116 as leading and trailing curtains of vapor, as depicted in FIG. 5. Although these curtains of vapor will diffuse to some extent in the longitudinal direction prior to passing through the distribution plate 152, it should be appreciated that it is unlikely that a uniform distribution of the sublimated source material in the longitudinal direction will be achieved. In other words, more of the sublimated source material will be distributed through the longitudinal end sections of the distribution plate 152 as compared to the middle portion of the distribution plate. However, as discussed above, because the system 10 conveys the substrates 14 through the vapor deposition apparatus 100 at a constant (non-stop) linear speed, the upper surfaces of the substrates 14 will be exposed to the same deposition environment regardless of any non-uniformity of the vapor distribution along the longitudinal aspect of the apparatus 100. The passages 126 in the distribution manifold 124 and the holes in the distribution plate 152 ensure a relatively uniform distribution of the sublimated source material in the transverse aspect of the vapor deposition apparatus 100. So long as the uniform transverse aspect of the vapor is maintained, a relatively uniform thin film layer is deposited onto the upper surface of the substrates 14 regardless of any non-uniformity in the vapor deposition along the longitudinal aspect of the apparatus 100.

As illustrated in the figures, it may be desired to include a debris shield 150 between the receptacle 116 and the distribution manifold 124. This shield 150 includes holes defined therethrough (which may be larger or smaller than the size of the holes of the distribution plate 152) and primarily serves to retain any granular or particulate source material from passing through and potentially interfering with operation of the movable components of the distribution manifold 124, as discussed in greater detail below. In other words, the debris shield 150 can be configured to act as a breathable screen that inhibits the passage of particles without substantially interfering with vapors flowing through the shield 150.

Referring to FIGS. 2 through 4 in particular, apparatus 100 desirably includes transversely extending seals 154 at each longitudinal end of the head chamber 110. In the illustrated embodiment, the seals define an entry slot 156 and an exit slot 158 at the longitudinal ends of the head chamber 110. These seals 154 are disposed at a distance above the upper surface of the substrates 14 that is less than the distance between the surface of the substrates 14 and the distribution plate 152, as is depicted in FIG. 4. The seals 154 help to maintain the sublimated source material in the deposition area above the substrates. In other words, the seals 154 prevent the sublimated source material from “leaking out” through the longitudinal ends of the apparatus 100. It should be appreciated that the seals 154 may be defined by any suitable structure. In the illustrated embodiment, the seals 154 are actually defined by components of the lower shell member 132 of the heated distribution manifold 124. It should also be appreciated that the seals 154 may cooperate with other structure of the vapor deposition apparatus 100 to provide the sealing function. For example, the seals may engage against structure of the underlying conveyor assembly in the deposition area.

Any manner of longitudinally extending seal structure 155 may also be configured with the apparatus 100 to provide a seal along the longitudinal sides thereof. Referring to FIGS. 2 and 3, this seal structure 155 may include a longitudinally extending side member that is disposed generally as close as reasonably possible to the upper surface of the underlying convey surface so as to inhibit outward flow of the sublimated source material without frictionally engaging against the conveyor.

Referring to FIGS. 2 and 3, the illustrated embodiment includes a movable shutter plate 136 disposed above the distribution manifold 124. This shutter plate 136 includes a plurality of passages 138 defined therethrough that align with the passages 126 in the distribution manifold 124 in a first operational position of the shutter plate 136 as depicted in FIG. 3. As can be readily appreciated from FIG. 3, in this operational position of the shutter plate 136, the sublimated source material is free to flow through the shutter plate 136 and through the passages 126 in the distribution manifold 124 for subsequent distribution through the plate 152. Referring to FIG. 2, the shutter plate 136 is movable to a second operational position relative to the upper surface of the distribution manifold 124 wherein the passages 138 in the shutter plate 136 are misaligned with the passages 126 in the distribution manifold 124. In this configuration, the sublimated source material is blocked from passing through the distribution manifold 124, and is essentially contained within the interior volume of the head chamber 110. Any suitable actuation mechanism, generally 140, may be configured for moving the shutter plate 136 between the first and second operational positions. In the illustrated embodiment, the actuation mechanism 140 includes a rod 142 and any manner of suitable linkage that connects the rod 142 to the shutter plate 136. The rod 142 is rotated by any manner of mechanism located externally of the head chamber 110.

The shutter plate 136 configuration illustrated in FIGS. 2 and 3 is particularly beneficial in that, for whatever reason, the sublimated source material can be quickly and easily contained within the head chamber 110 and prevented from passing through to the deposition area above the conveying unit. This may be desired, for example, during start up of the system 10 while the concentration of vapors within the head chamber builds to a sufficient degree to start the deposition process. Likewise, during shutdown of the system, it may be desired to maintain the sublimated source material within the head chamber 110 to prevent the material from condensing on the conveyor or other components of the apparatus 100.

Referring to FIG. 4, the vapor deposition apparatus 100 may further comprise a conveyor 160 disposed below the head chamber 110. This conveyor 160 may be uniquely configured for the deposition process as compared to the conveyors 48 discussed above with respect to the system 10 of FIG. 1. For example, the conveyor 160 may be a self-contained conveying unit that includes a continuous loop conveyor on which the substrates 14 are supported below the distribution plate 152. In the illustrated embodiment, the conveyor 160 is defined by a plurality of slats 162 that provide a flat, unbroken (i.e., no gaps between the slats) support surface for the substrates 14. The slat conveyor is driven in an endless loop around sprockets 164. It should be appreciated, however, that the invention is not limited to any particular type of conveyor 160 for moving the substrates 14 through the vapor deposition apparatus 100.

The present invention also encompasses various process embodiments for vapor deposition of a sublimated source material to form a thin film on a PV module substrate, and subsequent vapor treatment. The various processes may be practiced with the system embodiments described above or by any other configuration of suitable system components. It should thus be appreciated that the process embodiments according to the invention are not limited to the system configuration described herein.

For example, FIG. 6 shows an exemplary diagram of a process 600 where the substrate can be subjected to a load vacuum at 602, and heated to a deposition temperature at 604. Cadmium telluride can then be deposited onto the substrate (e.g., onto a cadmium sulfide layer on the substrate) to form a cadmium telluride layer at 606. The substrate can then be heated or cooled and subjected to a buffer vacuum in steps 608, 610, and 612. For example, the buffer vacuum of 610 can separate the cadmium telluride source material from intermixing with the cadmium chloride treatment. The cadmium telluride layer can be treated with cadmium chloride at 614, and subsequently annealed at 616. Finally, the substrate can be cooled at 618 and then exited from the system 620.

Desirably, the process embodiments include continuously conveying the substrates at a constant linear speed during the vapor deposition process.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A process of manufacturing a thin film cadmium telluride thin film photovoltaic device, the process comprising:
transporting a substrate from into a first vapor deposition chamber, wherein the first vapor deposition chamber comprises a source material, wherein the source material comprises cadmium telluride;
depositing a cadmium telluride layer on the substrate by heating the source material to produce source vapors that deposit onto the substrate;
transporting the substrate from the first vapor deposition chamber into a second vapor deposition chamber, wherein the second vapor deposition chamber comprises a treatment material, wherein the treatment material comprises cadmium chloride; and,
treating the cadmium telluride layer by heating the treatment material to produce treatment vapors that deposit onto the substrate,
wherein the substrate is transported through the first vapor deposition chamber and the second vapor deposition chamber at a system pressure that is less than about 760 Torr.

2. The process as in claim 1, wherein the first vapor deposition chamber comprises a receptacle for holding the source material, a heating manifold for heating the receptacle such that the source material vaporizes into source vapors, and a deposition plate defining holes through which the source vapors pass for deposition of a second thin film over the first thin film on the substrate.

3. The process as in claim 1, wherein the second vapor deposition chamber comprises a receptacle for holding the treatment material, a heating manifold for heating the receptacle such that the source material vaporizes into source vapors, and a deposition plate defining holes through which the source vapors pass for deposition of a second thin film over the first thin film on the substrate.

4. The process as in claim 1, further comprising:
transporting the substrate from a load vacuum chamber into a heating chamber positioned between the load vacuum chamber and the first vapor deposition chamber; and,
heating the substrate within the heating chamber to a first vapor deposition temperature prior to entering the first vapor deposition chamber.

5. The process as in claim 1, further comprising:
transporting the substrate from a load vacuum chamber into and through a series of heating chambers sequentially positioned between the load vacuum chamber and the first vapor deposition chamber; and,
heating the substrate within plurality of the heating chambers to a vapor deposition temperature prior to entering the first vapor deposition chamber.

6. The process as in claim 5, wherein the vapor deposition temperature is about 350° C. to about 600° C.

7. The process as in claim 1, further comprising:
transporting the substrate into a load vacuum chamber connected to a load vacuum pump; and,
drawing a vacuum in the load vacuum chamber using the load vacuum pump until an initial load pressure is reached in the load vacuum chamber,
wherein the substrate is transported from the load vacuum chamber to the first vapor deposition chamber.

8. The process as in claim 7, further comprising:
transporting the substrate from the load vacuum chamber into and through a plurality of fine vacuum chambers, wherein each fine vacuum chamber is connected to a fine vacuum pump to draw a deposition pressure.

9. The process as in claim 8, wherein the deposition pressure is about 10 mTorr to about 100 Torr.

10. The process as in claim 1, further comprising:
transporting the substrate into and through a vacuum buffer chamber positioned between the first vapor deposition chamber and the second vapor deposition chamber, wherein the vacuum buffer chamber is connected to a buffer vacuum pump configured to reduce the pressure within the vacuum buffer chamber to a buffer pressure;

11. The process as in claim 1, further comprising
transporting the substrate from the first deposition chamber into and through a cooling chamber positioned between the first vapor deposition chamber and the second vapor deposition chamber;
cooling the substrate to a vapor treatment temperature prior to transporting the substrate into the second deposition chamber.

12. The process as in claim 11, wherein the vapor treatment temperature is about 350° C. to about 500° C.

13. The process as in claim 1, wherein the substrate is transported through the first vapor deposition chamber and the second vapor deposition chamber at a system pressure that is about 1 mTorr to about 250 mTorr.

14. The process as in claim 1, further comprising:
transporting the substrate from the second deposition chamber into and through an annealing chamber after the second deposition chamber;
annealing the substrate at an anneal temperature of about 350° C. to about 500° C.

15. A process of manufacturing a thin film cadmium telluride thin film photovoltaic device, the process comprising:
transporting a substrate into a load vacuum chamber connected to a load vacuum pump;
drawing a vacuum in the load vacuum chamber using the load vacuum pump until an initial load pressure is reached in the load vacuum chamber;
transporting the substrate from the load vacuum chamber into a first vapor deposition chamber, wherein the first vapor deposition chamber comprises a source material, wherein the source material comprises cadmium telluride;
depositing a cadmium telluride layer on the substrate by heating the source material to produce source vapors that deposit onto the substrate;
transporting the substrate from the first vapor deposition chamber into a vacuum buffer chamber, wherein the vacuum buffer chamber is connected to a buffer vacuum pump configured to reduce the pressure within the vacuum buffer chamber to a buffer pressure;
transporting the substrate from the vacuum buffer chamber into a second vapor deposition chamber, wherein the second vapor deposition chamber comprises a source material, wherein the treatment material comprises cadmium chloride; and,
treating the cadmium telluride layer by heating the treatment material to produce treatment vapors that deposit onto the substrate,
wherein the substrate is transported through the first vapor deposition chamber, the vacuum buffer chamber, and the second vapor deposition chamber at a system pressure that is less than about 760 Torr.

16. The process as in claim 15, further comprising:
transporting the substrate from the load vacuum chamber into a heating chamber positioned between the load vacuum chamber and the first vapor deposition chamber; and,
heating the substrate within the heating chamber to a first vapor deposition temperature prior to entering the first vapor deposition chamber.

17. The process as in claim 15, further comprising:
transporting the substrate from the load vacuum chamber into and through a series of heating chambers sequentially positioned between the load vacuum chamber and the first vapor deposition chamber; and,
heating the substrate within plurality of the heating chambers to a vapor deposition temperature prior to entering the first vapor deposition chamber, wherein the vapor deposition temperature is about 350° C. to about 600° C.

18. The process as in claim 17, further comprising
transporting the substrate from the first deposition chamber into and through a cooling chamber positioned between the first vapor deposition chamber and the second vapor deposition chamber;
cooling the substrate to a vapor treatment temperature prior to transporting the substrate into the second deposition chamber, wherein the vapor treatment temperature is about 350° C. to about 500° C.

19. The process as in claim 15, wherein the substrates are continuously transported through the first vapor deposition chamber, the vacuum buffer chamber, and the second vapor deposition chamber at a substantially constant rate.

20. The process as in claim 15, wherein the substrate is transported through the first vapor deposition chamber, the vacuum buffer chamber, and the second vapor deposition chamber at a system pressure that is about 1 mTorr to about 250 mTorr.
